(19) United States
(12) Patent Application Publication
(10) Pub. No.: US 2013/0015488 A1
(43) Pub. Date: Jan. 17, 2013

(54) LIGHT EMITTING DIODE PACKAGE AND METHOD FOR FABRICATING THE SAME

(71) Applicants: Sun Jin Yoon, Ansan-si (KR); Kwang Yong Oh, Ansan-si (KR); Yun Jeong Bae, Ansan-si (KR)

(72) Inventors: Sun Jin Yoon, Ansan-si (KR); Kwang Yong Oh, Ansan-si (KR); Yun Jeong Bae, Ansan-si (KR)

(73) Assignee: SEOUL SEMICONDUCTOR CO., LTD., Ansan-city (KR)

(21) Appl. No.: 13/638,353

(22) PCT Filed: Jan. 24, 2011
(86) PCT No.: PCT/KR11/00479

§ 371 Date: Sep. 28, 2012

(30) Foreign Application Priority Data
Apr. 16, 2010 (KR) 10-2010-0035403

(51) Int. Cl. H01L 33/52; H01L 33/60; H01L 33/62

(52) U.S. Cl. 257/98; 257/99; 438/27; 257/E33.066; 257/E33.068; 257/E33.059

(57) ABSTRACT

The present invention relates to a light emitting diode (LED), which enables a filler material for filling up a hole or opening of a substrate to prevent a resin of an encapsulant formed on the substrate from leaking and to enhance cohesion between the substrate and a resin portion formed in the hole or opening, and a method for fabricating the LED package. According to an embodiment of the present invention, there is provided an LED package, which comprises an LED chip; a substrate having the LED chip mounted thereon, the substrate having a hole or opening formed therein; an encapsulant formed on the substrate to encapsulate the LED chip; a resin portion for filling in the hole or opening; and a filler material for filling up a gap between the resin portion and the substrate.

### CROSS-REFERENCE TO RELATED APPLICATIONS

This application is the National Stage Entry of International Application PCT/KR2011/000479, filed on Jan. 24, 2011, and claims priority from and the benefit of Korean Patent Application No. 10-2010-0035403, filed on Apr. 16, 2010, both of which are incorporated herein by reference for all purposes as if fully set forth herein.

### BACKGROUND

1. Field

The present invention relates to a light emitting diode (LED) package and a method for fabricating the same, and more particularly, to an LED package which enables a filler material for filling up a hole or opening of a substrate to prevent a resin of an encapsulant formed on the substrate from leaking and to enhance cohesion between the substrate and a resin portion formed in the hole or opening, and a method for fabricating the LED package.

2. Discussion of the Background

In general, an LED is an element in which electrons and holes are combined in P-N semiconductor junctions by application of current to thereby emit light. The LED is typically formed to have a package structure having an LED chip mounted thereto.

FIGS. 1 and 2 show an external structure of an LED package 1 fabricated according to a prior art. The LED package 1 shown in FIGS. 1 and 2 has a plurality of lead frames 12 and 13. A reflector 11 is disposed on the plurality of lead frames 12 and 13, thereby reflecting the light generated in an LED chip 14.

FIG. 3 is a sectional view taken along line I-I of the LED package shown in FIG. 1, in which an inside 111 of the reflector 11 is filled with at least one molding materials, e.g., an encapsulant 15 made of a light-transmitting resin. The inside 111 of the reflector 11 is filled with the encapsulant 15 while it comes into direct contact with the plurality of the lead frames 12 and 13.

Since the LED package 1 having the structure is necessarily mounted in a thin mobile device such as a cellular phone, there is a limit on designing the LED package, i.e., the LED package should be maintained to be thin. Therefore, as shown in FIG. 3, the lead frames 12 and 13 are simplified to be formed as thin as possible.

However, in case of such a thin LED package 1, cohesion between the thin lead frames 12 and 13 and a resin portion 123 formed between the thin lead frames 12 and 13 is very weak, as shown in FIG. 3, and there is generated a “resin leakage” that a resin of the encapsulant 15 leaks into a gap C between the resin portion 123 and the lead frames 12 and 13.

Since the resin leakage is generated by interaction in atomic unit, referred to as “capillary” (see an enlarged view of FIG. 3), it is very difficult to avoid the resin leakage that a molding material leaks in an LED package for mobile device, of which the cohesion is weak even though the gap is formed as narrow as possible.

### SUMMARY

An object of the present invention is to provide an LED package, which enables a filler material for filling up a hole or opening of a substrate to prevent a resin of an encapsulant formed on the substrate from leaking and to enhance cohesion between the substrate and a resin portion formed in the hole or opening, and a method for fabricating the LED package.

According to an aspect of the present invention, there is provided an LED package, which comprises an LED chip; a substrate having the LED chip mounted thereon, the substrate having a hole or opening formed therein; an encapsulant formed on the substrate to encapsulate the LED chip; a resin portion for filling in the hole or opening; and a filler material for filling up a gap between the resin portion and the substrate.

The substrate may comprise a plurality of lead frames. A reflector may be formed on the lead frames, and the resin portion may be a portion of the reflector.

The filler material may comprise at least one of hexamethyldisiloxane, hexamethyldisilazane and siloxane oligomer.

According to another aspect of the present invention, there is provided a method for fabricating an LED package, which comprises the steps of: preparing a substrate having a hole or opening formed therein; forming a resin portion in the hole or opening; mounting an LED chip on the substrate; and disposing a filler material to fill up a gap between the resin portion and the substrate.

The substrate may comprise a plurality of lead frames, and the hole or opening may be defined between adjacent ones of the lead frames.

The disposing step may comprise the steps of applying the filler material to surfaces of the plurality of lead frames; and introducing the filler material into the hole or opening.

The method may further comprise removing the filler material disposed on the surfaces of the plurality of lead frames through a plasma treatment after the introducing step.

According to embodiments of the present invention, a filler material for filling in a hole or opening of a substrate makes it possible to prevent a resin of an encapsulant formed on the substrate from leaking through the hole or opening of the substrate and to enhance cohesion between the substrate and a resin portion formed in the hole or opening. Thus, as the cohesion is enhanced by the filler material, the light emitting efficiency of an LED chip can be maintained for a long period of time by protecting the LED chip from sulfur, heat and moisture that are environmental factors, and accordingly, the light emitting lifetime of the LED package can be improved.

In addition, according to embodiments of the present invention, the filler material disposed on a surface of the substrate can be removed through a plasma treatment, so that it is possible to reduce the interface delamination between the substrate and the encapsulant, and the like.

### BRIEF DESCRIPTION OF THE DRAWINGS

FIGS. 1 and 2 are perspective views showing an external structure of a conventional LED package.

FIG. 3 is a sectional view taken along line I-I in FIG. 1.

FIG. 4 is a sectional view illustrating an LED package according to an embodiment of the present invention.

FIG. 5 is a view showing a state that a filler material is removed by a plasma treatment in the LED package shown in FIG. 4.

FIG. 6 shows photographs illustrating the degree of improvement in a conventional LED package and an LED package according to the embodiment of the present invention.

FIG. 7 is a flowchart illustrating a method for fabricating an LED package according to another embodiment of the present invention.

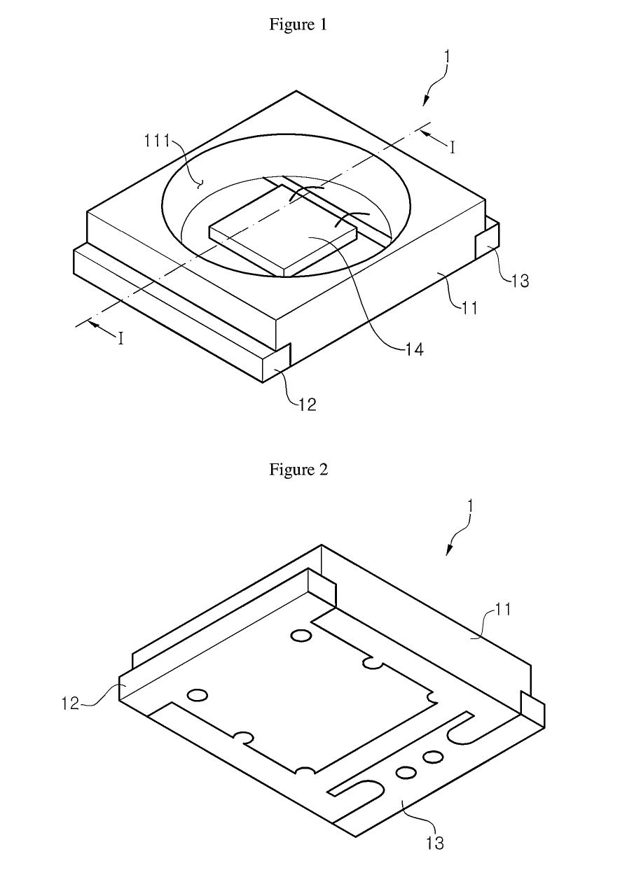

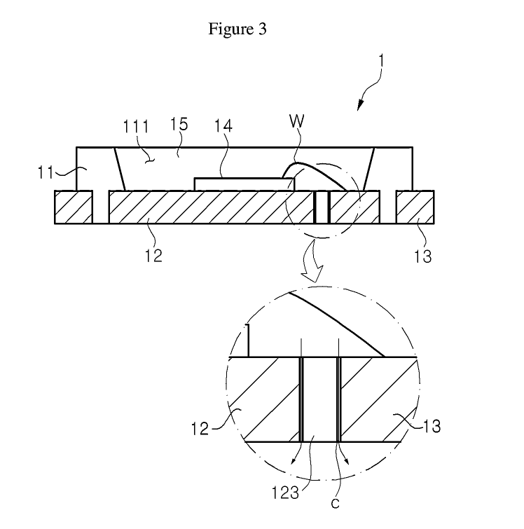

### DETAILED DESCRIPTION OF ILLUSTRATED EXEMPLARY EMBODIMENTS

Hereinafter, preferred embodiments of the present invention will be described in detail with reference to the accompanying drawings. The following embodiments are provided only for illustrative purposes so that those skilled in the art can fully understand the spirit of the present invention. Therefore, the present invention is not limited to the following embodiments but may be implemented in other forms. In the drawings, the widths, lengths, thicknesses and the like of elements may be exaggerated for convenience of illustration. Like reference numerals indicate like elements throughout the specification and drawings.

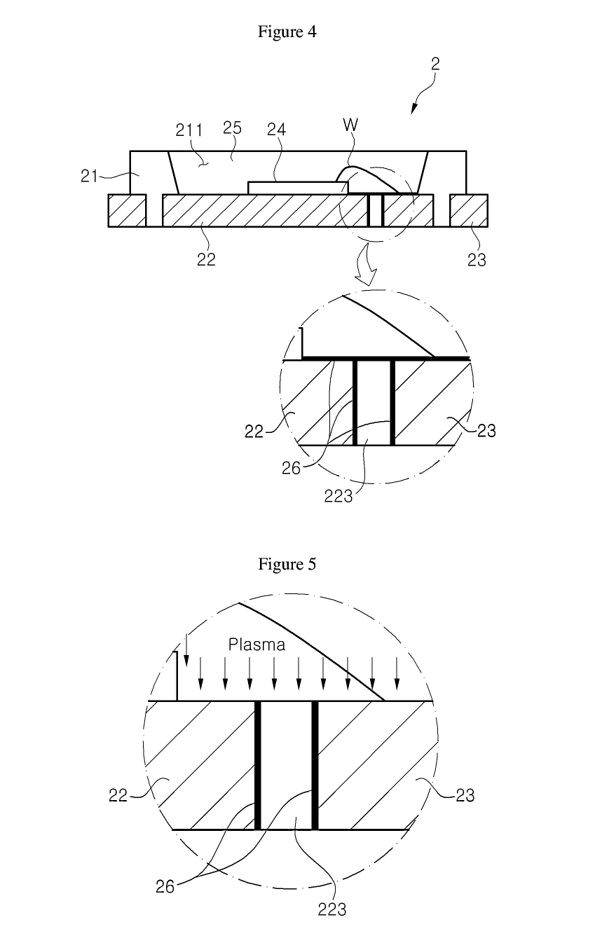

Referring to FIG. 4, an LED package 2 according to an embodiment of the present invention comprises an LED chip 24 and a substrate having the LED chip 24 mounted thereon. The substrate may be a plurality of lead frames 22 and 23 disposed with a hole or opening interposed therebetween.

A reflector 21 is formed on the plurality of lead frames 22 and 23. The reflector 21 is a part of a resin portion 223 formed in the hole or opening. A material for the reflector 21 may be, for example, polyphthalamid (PPA). The reflector 21 may be molded integrally with the plurality of lead frames 22 and 23, and the internal structure of the LED package 2 may be variously designed.

A through-hole (not shown) may be partially formed in the plurality of lead frames 22 and 23 so as to increase the coupling force between the lead frames and the reflector 21. The plurality of lead frames 22 and 23 may be firmly supported by the reflector 21 coupled to the through-hole.

An encapsulant 25 is formed by filling the inside of the reflector 21 with a light-transmitting resin, e.g., silicon resin or epoxy resin. The encapsulant 25 encapsulates the LED chip 24 mounted on one lead frame 22 of the plurality of lead frames 22 and 23 and a bonding wire W through which the LED chip 24 is electrically connected to the other lead frame 23 to thereby protect them from the outside.

A filler material 26 is formed to be in contact with the resin portion 223 formed in the hole or opening of the substrate, and the hole or opening is filled with the filler material 26. The filler material 26 comprises at least one of hexamethyldisiloxane, hexamethyldisilazane and siloxane oligomer, all of which have a low viscosity.

Specifically, the filler material 26 is easily applied to surfaces of the plurality of lead frames 22 and 23 by a simple dispensing process and thus injected into a gap between the resin portion 223 and the lead frames 22 and 23. As well shown in an enlarged view of FIG. 4, the filler material 26 is formed on top surfaces of the lead frames 22 and 23 near the resin portion 223 and the gap between the resin portion 223 and the lead frames 22 and 23.

Particularly, the filler material 26 injected into the gap between the resin portion 223 and the lead frames 22 and 23 is hydrolyzed by being heated at about 160° C. for the purpose of curing. Accordingly, the gap between the resin portion 223 and the lead frames 22 and 23 is filled with the filler material 26, so that it is possible to prevent the resin of the encapsulant 25 from leaking. However, the filler material 26 partially formed on the plurality of lead frames 22 and 23 is preferably removed, for example, through a plasma treatment, in consideration of the interface delamination of the encapsulant 25. FIG. 5 shows a state where unnecessarily scattered filter material is removed by performing a plasma treatment for the top surfaces of the plurality of lead frames 22 and 23.

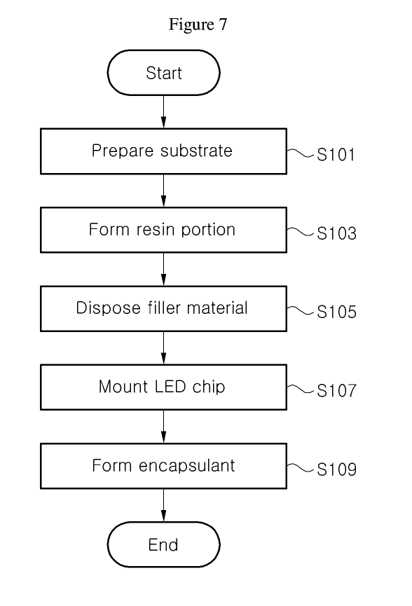

A method for fabricating an LED package configured as described above will be described with reference to FIG. 7 as follows.

FIG. 7 is a flowchart illustrating a method for fabricating an LED package according to another embodiment of the present invention.

First, a substrate having a hole or opening formed therein is prepared (S101). Here, the substrate is a plurality of lead frames 22 and 23 disposed adjacent to each other.

Then, a resin portion 223 is formed in the hole or opening of the substrate (S103). The resin portion 223 may be a portion of a reflector 21 formed on the plurality of lead frame 22 and 23, and the reflector 21 has a structure for exposing the top of an LED chip 24.

A filler material 26 is then disposed so as to fill up the gap between the resin portion 223 and the lead frames 22 and 23 (S105). As the filler material 26 includes a material with strong adhesion and moistureproof, it is possible to enhance the adhesion between the resin portion 223 and the lead frames 22 and 23. Further, as the filler material has excellent moistureproof, it is possible to prevent a resin of an encapsulant 25 from leaking to the outside.

More specifically, if the filler material 26 is applied to the lead frames 22 and 23 near the resin portion 223, a portion of the applied filler material 26 flows into the gap between the resin portion 223 and the lead frames 22 and 23, and the filler material is hydrolyzed by being heated, for example, at about 160° C. for the purpose of curing. Accordingly, the filler material 26 is formed between the resin portion 223 and the lead frames 22 and 23 to fill up a fine gap therebetween, so that it is possible to prevent the resin of the encapsulant 25 formed on the lead frames 22 and 23 from leaking.

Alternatively or optionally, the filler material 26 formed on surfaces of the lead frames 22 and 23 near the resin portion 223 is removed through a plasma treatment. Accordingly, it is possible to reduce the delamination of the encapsulant 25, which is generated at an interface between the encapsulant 25 and the lead frames 22 and 23.

Then, the LED chip 24 is mounted on the substrate (S107). That is, the LED chip 24 may be mounted on one lead frame 22 of the plurality of lead frames 22 and 23, and may be electrically connected to the other lead frame 23 through a bonding wire W.

Although it has been described in this embodiment that the LED chip 24 is mounted on the substrate after the filler material 26 is formed, the present invention is not limited thereto. For example, the fabrication order may be changed in consideration of a thickness of the LED chip 24. That is, in a case where the LED chip is thin, since the filler material may be applied to the LED chip, the LED chip may be mounted on the substrate after the filler material is formed. In a case where the LED chip is thick, i.e., where the LED chip is thicker than the filler material, the filler material may be formed after the LED chip is mounted on the substrate.

Although it has been described in this embodiment that the single LED chip 24 is mounted on the substrate, the present invention is not necessarily limited thereto. For example, a plurality of LED chips may be mounted on the substrate. The LED chip 24 may be mounted besides the plurality of lead frames 22 and 23.

Subsequently, the encapsulant 25 is formed to encapsulate the LED chip 24 (S109). Although a top surface of the encapsulant 25 is formed in a concave shape, the present invention is not limited thereto. For example, the top surface of the encapsulant may be formed in a flat or convex shape.

As described above, it is possible to prevent the resin of the encapsulant 25 from leaking by the filler material 26 disposed to fill up the fine gap between the resin portion 223 formed in the hole or opening of the substrate and the lead frames 22 and 23, and the cohesion between the substrate and the resin portion 223 can be more enhanced. Thus, the durability of the LED package can be enhanced.

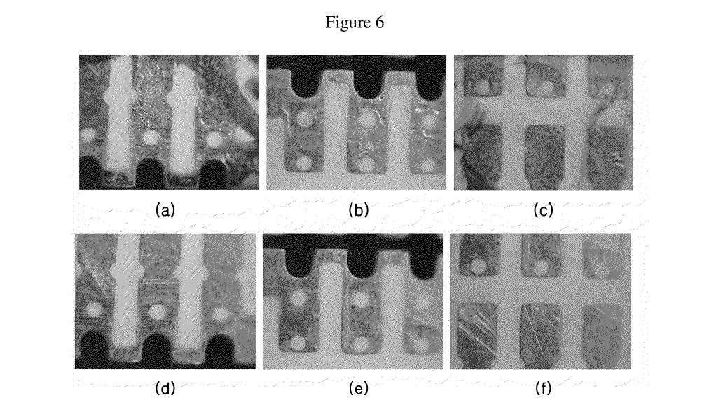

FIG. 6 shows the comparison of pre-improvements (corresponding to (a) to (c)) with post-improvements (corresponding to (d) to (f)) of an LED package, from which it can be seen that the resin leakage in the post-improvement is remarkably reduced as compared with that in the pre-improvement. FIG. 6 (a) to FIG. 6 (c) are lower surfaces of a conventional LED package, and FIG. 6 (d) to FIG. 6 (f) are lower surfaces of the LED package to which the filler material 26 is applied according to the embodiment of the present invention.

The present invention is not limited to the embodiments described above but defined by the claims. Further, it will be understood by those skilled in the art that various changes and modifications can be made thereto within the scope of the invention defined by the claims.

1. A light emitting diode (LED) package, comprising:
an LED chip;
a substrate on which the LED chip is disposed, the substrate comprising a hole formed therein;
an encapsulant disposed on the substrate to encapsulate the LED chip;
a resin portion disposed in the hole; and
a filler material disposed in a gap between the resin portion and the substrate.

2. The LED package of claim 1, wherein the substrate comprises a plurality of lead frames.

3. The LED package of claim 1, wherein the filler material comprises at least one of hexamethyldisiloxane, hexamethyldisilazane and siloxane oligomer.

4. A method for fabricating an LED package, comprising:
making a hole in a substrate;
forming a resin portion in the hole;
mounting an LED chip on the substrate; and
disposing a filler material to fill up a gap between the resin portion and the substrate.

5. The method of claim 4, wherein the substrate comprises a plurality of lead frames, and the hole exists between adjacent ones of the lead frames.

6. The method of claim 5, wherein the disposing comprises applying the filler material to surfaces of the plurality of lead frames; and introducing the filler material into the hole.

7. The method of claim 6, further comprising removing the filler material disposed on the surfaces of the plurality of lead frames through a plasma treatment after the introduction of the filler material.

8. The method of claim 7, further comprising:
heating the filler material at about 160° C.

9. The LED package of claim 2, further comprising a reflector disposed on the lead frames.

10. The LED package of claim 9, wherein the resin portion and the reflector are formed of a same material.

11. A light emitting diode (LED) package, comprising:
an LED chip;
a first and a second lead frames which are arranged side by side, the LED chip being disposed on the first lead frame;
an opening provided between the first and the second lead frames;
an encapsulant disposed on the first lead frame to encapsulate the LED chip;
a resin portion disposed in the hole; and
a filler material disposed in a gap between the resin portion and the first lead frame.

12. The LED package of claim 11, further comprising a reflector disposed on the first lead frame.

13. The LED package of claim 11, wherein the filler material comprises at least one of hexamethyldisiloxane, hexamethyldisilazane and siloxane oligomer.

14. The LED package of claim 12, wherein a surface of the reflector is inclined with respect to a surface of the first lead frame.

15. The LED package of claim 14, wherein the reflector and the resin portion are formed of a same material.

16. The LED package of claim 11, further comprising a wire which connects the LED chip and the second lead frame.
